(19) United States
(12) Patent Application Publication
(10) Pub. No.: US 2018/0005979 A1
(43) Pub. Date: Jan. 4, 2018

(54) SIMULTANEOUS DOUBLE WIRE WEDGE BONDING METHOD, SYSTEM, KIT AND TOOL

(71) Applicant: Simon Savard, Quebec (CA)

(72) Inventor: Simon Savard, Quebec (CA)

(73) Assignee: Ciena Corporation, Hanover, MD (US)

(21) Appl. No.: 15/199,548

(22) Filed: Jun. 30, 2016

(51) Int. Cl. H01L 23/00; B23K 20/10

(52) U.S. Cl. CPC H01L 24/85; H01L 24/09; H01L 24/49; H01L 24/78; B23K 20/106; H01L 2224/49427; H01L 2224/78611; H01L 2224/78621; H01L 2924/14; H01L 2224/04042

(57) ABSTRACT

A wedge bonding method for simultaneously connecting two wires to a first component and then to a second component includes a) feeding the two wires side by side through a guide channel located at a lower end of a bonding wedge tool, b) positioning the bonding wedge tool over the first component and performing a first bond connection thereon, c) positioning the bonding wedge tool over the second component and performing a second bond connection thereon; and d) breaking tails of the two wires near the second bond connection.

### FIELD OF INVENTION

The present invention relates generally to a wire wedge bonding method, tool, kit, and system for simultaneously connecting two wires from a first to a second electronic component.

### BACKGROUND

The ever increasing operating frequencies of electronic components come along with complications. At a radio frequency (RF), electrical current of signals flows mainly at the surface of a conductor. This phenomenon is known as the “skin effect”. Increasing the surface area of the conductor may ease the flow of the electrical current of the RF signals, thereby reducing its inductance.

Connecting electronic components with two wires instead of one wire will increase the surface area of the conductor and therefore reduce the inductance of such wire bond connections. Such a double wire bond connection will also increase its reliability, resulting from the increased redundancy in the wire bond connections.

It is presently possible to perform double wire bond connections “sequentially,” or in other words, to bond one wire after the other, by, for example, an existing single wire wedge bonding system such as the 8060 Automatic gold aluminum bonder manufactured by Kulicke & Soffa.

However, such existing double wire wedge bonding systems are plagued with several drawbacks. They are generally fully-automatic and are therefore expensive. The time required to perform double wire bond connections for a given integrated circuit (IC) package is twice the time required for single wire bond connections. Performing sequential double wire bond connections increases the probability of having the two wires contact each other and/or of generating cross-talk between the two wires. Further, the two wire bond segments, possibly of unequal length, may cause a skew delay.

In addition, the size of bonding pads, to which wires are bond connected, is generally defined by chip designers/manufacturers. Double wire bond connections provide more flexibility to maximize the use of all the area of the bonding pads.

In view of the above, there is a need for a method, tool, kit, and system that would allow simultaneous double wire bond connections and that would be able to reduce some of the effects of the existing double wire wedge bonding systems discussed above.

### SUMMARY

In one aspect, one or more embodiments of the invention relate to a wedge bonding method for simultaneously connecting two wires to a first component and then to a second component. The wedge bonding method comprises a) feeding the two wires side by side through a guide channel located at a lower end of a bonding wedge tool, b) positioning the bonding wedge tool over the first component and performing a first bond connection thereon, c) positioning the bonding wedge tool over the second component and performing a second bond connection thereon; and d) breaking tails of the two wires near the second bond connection.

In another aspect, one or more embodiments of the invention relate to a bonding wedge tool for simultaneously connecting two wires to a first component, and then to a second component. A bonding wedge tool comprises a vertical hole extending therethrough, from a top aperture to a bottom aperture of the bonding wedge tool, a back face and a bottom face at a tapered lower end of the bonding wedge tool; and a guide channel opening on the back and the bottom faces.

Other aspects of the invention will be apparent from the following description and the appended claims.

### BRIEF DESCRIPTION OF DRAWINGS

Certain embodiments of the invention will be described with reference to the accompanying drawings. However, the accompanying drawings illustrate only certain aspects or implementations of the invention by way of example and are not meant to limit the scope of the claims.

FIG. 1 is a perspective view of a wire wedge bonding system in accordance with one or more embodiments of the invention.

FIG. 2 is schematic front view of the wire wedge bonding system of FIG. 1.

FIGS. 3 and 3A are two side perspective views of the lower end of a bonding wedge tool in accordance with one or more embodiments of the invention. FIG. 3B is a close-up view of alternative configuration of the lower end of a bonding wedge tool in accordance with one or more embodiments of the invention.

FIGS. 4 and 4A are two close-up views of the lower end of the boding wedge tool shown in FIG. 3. FIG. 4B shows an alternate bonding wedge tool, in accordance with one or more embodiments of the invention.

FIGS. 5 and 5A are bottom perspective views of the bonding wedge tool of FIG. 3.

FIG. 6 shows a flow chart in accordance with one or more embodiments of the invention.

FIG. 7 is a top perspective view showing an integrated circuit (IC) package connected to a substrate with both single and double wire bond connections.

FIGS. 8 and 8A are close-up views of four double wire bond connections.

FIGS. 9 and 9A are top views of an integrated circuit (IC) package showing three double wire bond connections and an empty bonding pad.

FIGS. 10A and 10B are two different views of double wire bond connections made with the simultaneous double wire wedge bonding tool, in accordance with one or more embodiments.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

In addition, it will be appreciated that positional descriptions such as “top”, “bottom,” “side,” “lower,” “upper,” and the like should, unless otherwise indicated, be taken in the context of the figures and should not be considered as limiting or as implying a required orientation during use.

In general, embodiments of the claimed invention relate to a method, a tool, a kit, and a system for simultaneously performing a double wire bond connection. One or more embodiments of the invention may allow modification of an existing single wire wedge bonding system, which may include a bonder for generating ultrasonic energy required to connect wires to electronic components, into a simultaneous double wire wedge bonding system. In one or more embodiments of the invention, other types of generators and bonders may be used, for providing the required bonding energy.

One or more embodiments of such a simultaneous double wire wedge bonding system may also include a bonding wedge tool modified for simultaneously connecting two wires side by side (in parallel), without crossing one another. In other words, the wires are fed in parallel through the bonding wedge tool.

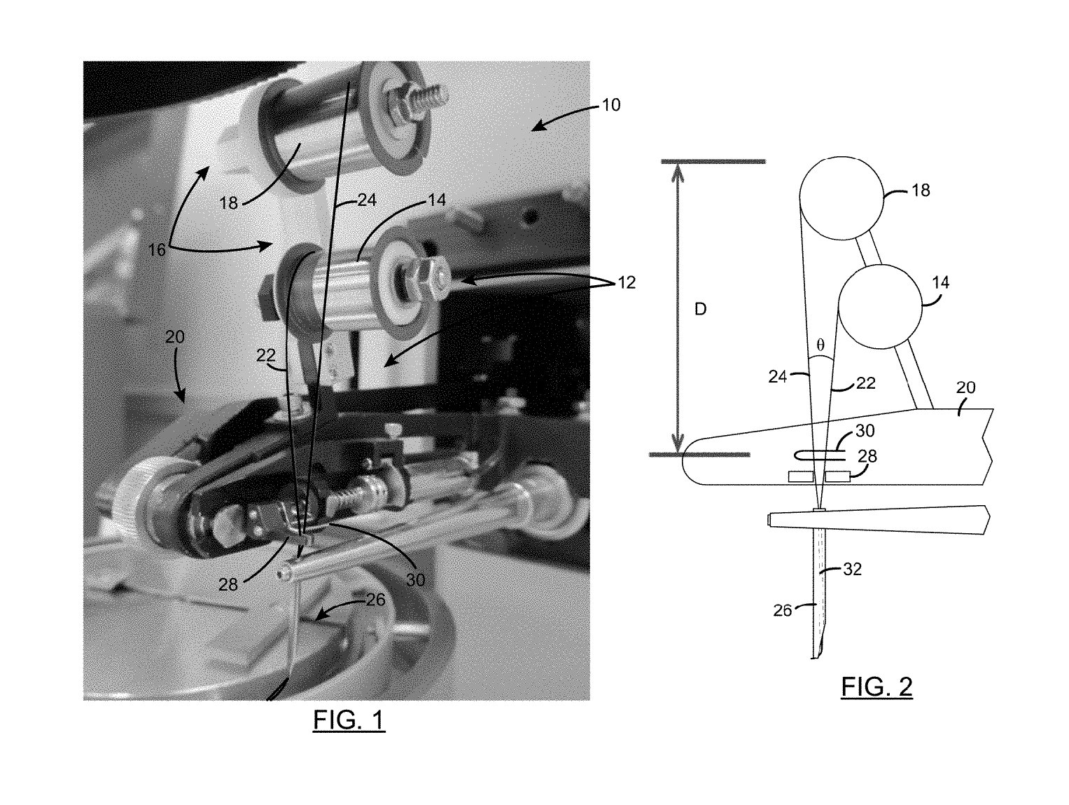

Referring to FIG. 1, a wire wedge bonding system 10 according to one or more embodiments of the invention is shown. The wire wedge bonding system 10 includes a first wire spool support 12 to support a first wire spool 14. The wire wedge bonding system 10 also includes a second wire spool support 16 to support a second wire spool 18. Each of the first and the second wire spools 14 and 18 has a cylindrical body on which a wire is wound. In one or more embodiments of the inventions, a wire 22 on the first wire spool 14, and a wire 24 on the second wire spool 18 may be gold wires. The cylindrical body has a central hole defining a rotation axis. Each of the first and the second wire spool supports 12 and 16 may have any appropriate structure capable of maintaining the corresponding wire spool at a predetermined position with its central hole extending horizontally, and allowing a rotation of the cylindrical body about its rotation axis to unwound the wire from the wire spool. In one or more embodiments illustrated in FIG. 1, each of the first and the second wire spool supports 12 and 16 includes a spindle extending through the central hole of the corresponding wire spool. In one or more embodiments, each of the spindles may also have a threaded end and a nut may be provided to maintain the wire spool on the spindle. In FIG. 1, the second wire spool support 16 is connected to the first wire spool support 12. In one or more embodiments, the second wire spool support 16 may be attached elsewhere on the wire wedge bonding system 10, such as to an existing frame 20, as long as the two wires 22, 24 of the first and the second wire spools 14, 18 do not cross and enter a bonding wedge tool 26 side by side. In one or more embodiments, the second wire spool support 16 may be removably connected to the wire wedge bonding system 10, allowing to use the system for either single or double wire wedge bonding.

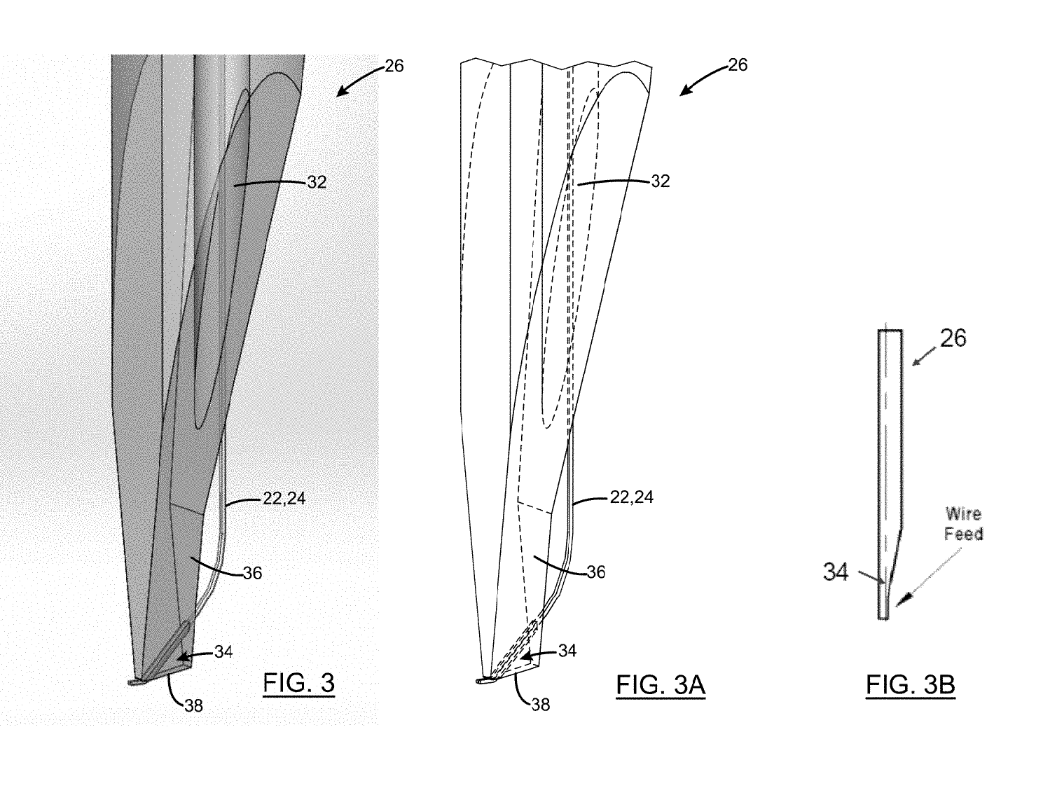

Still referring to FIG. 1, and also to FIG. 2, the second wire spool 18 is located above the first wire spool 14 and their rotation axes are slightly offset. In one or more embodiments, the second wire spool 18 may be positioned at a distance D between 5 and 80 cm from the wedge bonding tool, and the first and the second wire spools 14, 18 may be spaced apart by an angle θ varying between 20 and 40 degrees. The first and the second wire spools 14, 18 are positioned so as to maintain proper tension within the two wires 22, 24, by having the second wire spool support 16 higher and offset relative to the first wire spool support 12.

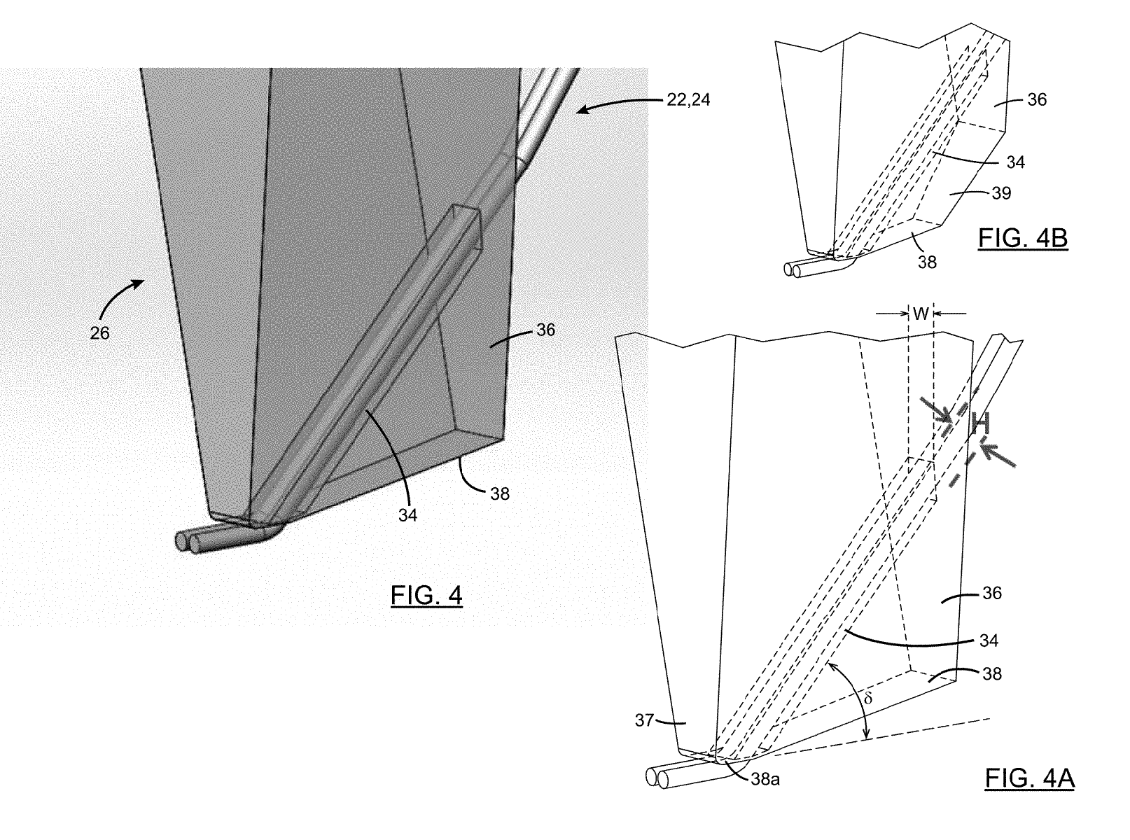

In one or more embodiments, the wire wedge bonding system 10 may also be provided with a U-shaped wire guide 30, located above a wire clamp 28, and affixed to the existing frame 20 of the wire wedge bonding system 10. The two wires 22, 24 from the first and the second wire spools 14 and 18 are passed through the bonding wedge tool 26 as described further below, which is mounted at a position underneath the first and the second wire spools 14 and 18. The wire guide 30 allows bringing the two wires 22, 24 from the first and the second wire spools 14 and 18 closer to one another, so as to avoid as much as possible crossing of the wires within the wire clamp 28. Even when the two wires 22, 24 cross within the wire clamp 28, the two wires 22, 24 do not cross within an inclined (or angled) guide channel 34 at an end of the bonding wedge tool 26 (shown in FIG. 3A), as will be explained in more detail later on in the description. The guide channel 34 may be at any of a variety of angles with respect to the bonding wedge tool, such as for example, from 20-65 degrees. In addition, in FIG. 3A shows the wire may be fed from the top of the spools, through the center of the body of the tool, existing from the bottom and re-enter the guide channel 34. Alternatively, as shown in FIG. 3B, the wire may be fed from behind the tool directly into the guide channel 34, i.e., at any angle between 20 and 65 degrees.

Referring to FIG. 2, the bonding wedge tool 26 is provided with a vertical hole 32 extending through it. The vertical hole (or bore) 32 opens at the top end and toward the bottom end of the bonding wedge tool 26. In one or more embodiments of the bonding wedge tool 26, the vertical hole 32 may not be present. The wire clamp 28 may be positioned above the bonding wedge tool 26, and substantially in alignment with the vertical hole 32. The wire clamp 28 may alternatively be positioned behind the bonding wedge tool 26, guiding the two wires 22, 24 into the guide channel 34.

The wire clamp 28 is shaped and configured such that the two wires 22, 24 are slightly pinched, to maintain a tension within the two wires 22, 24, and such that they can slide through it. In FIG. 2, the wire clamp 28 is formed by two brackets, which may be electro-mechanically activated, for creating a rectangular aperture through which the two wires 22, 24 can slide. The two brackets are connected to the existing frame 20 of the wire wedge bonding system 10, and include arms extending substantially parallel to the rotation axes of the first and the second wire spools 14 and 18. The two wires 22, 24 exiting the wire clamp 28 then enter the vertical hole 32 (shown in FIGS. 3, 3A) extending through the bonding wedge tool 26. The relative position of the first and the second wire spools 14, 18 and the wire clamp 28 may allow the two wires 22, 24 to be fed with a slight angle which is gradually reduced to 0° once inside the inclined guide channel 34 (shown in FIG. 3A). Alternatively, as shown in FIG. 3B, the two wires 22, 24 may be fed along the bonding wedge tool 26. While the two wires 22, 24 may inadvertently touch one another within the vertical hole 32 of the bonding wedge tool 26, they may not cross since each of the two wires is under tension from its corresponding wire spool and is subject to breaking if there is interference between the two wires 22, 24.

In FIG. 2, D represents the spool to wedge distance. This distance may be optimized depending on the number of spools on the double bond wire tool in order to ensure that the parallel wires do not cross. As described above, the distance D is between 5 cm and 80 cm. Optimally, the distance D may be 10 cm.

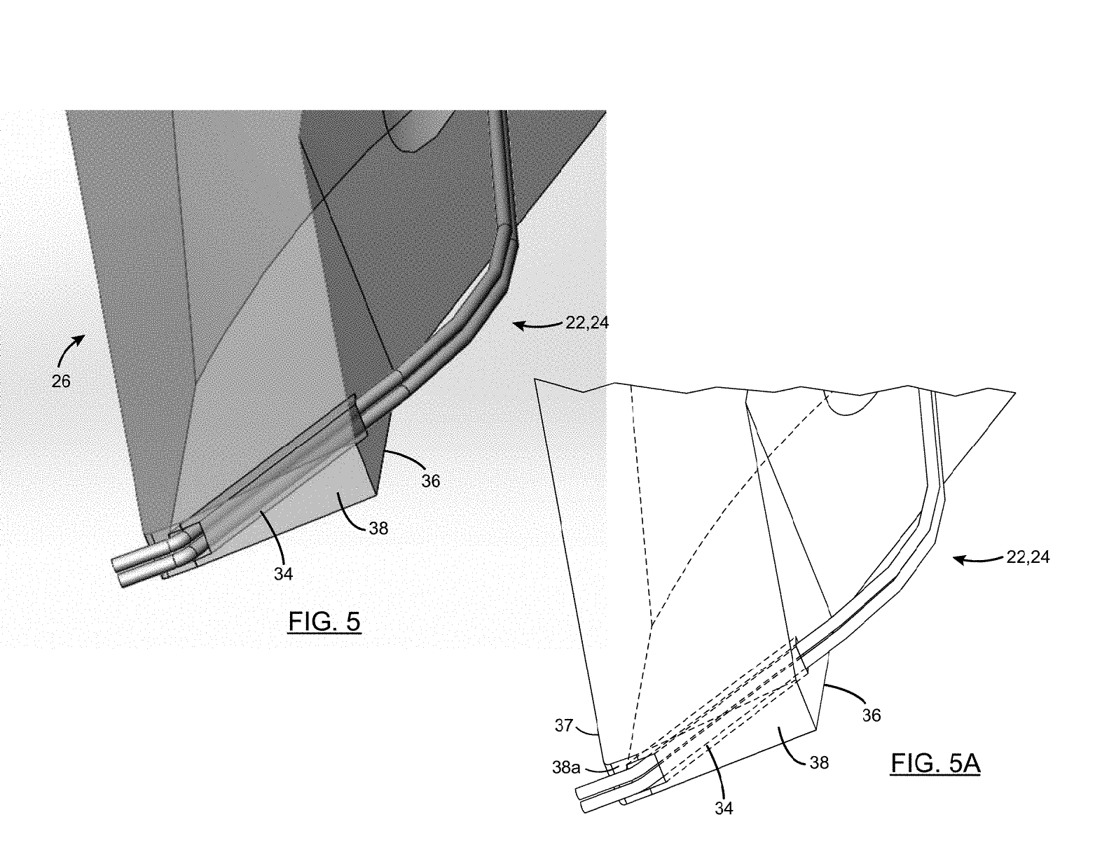

Referring now to FIGS. 3, 3A, 4, 4A and 4B, the lower end of the bonding wedge tool 26 according to one or more embodiments is shown. The bonding wedge tool 26 may have a substantially elongated shape with a profiled and a tapered lower end, defining a wedge tip. In FIGS. 3, 3A, 4, 4A and 4B the bonding wedge tool 26 includes the vertical hole 32, as discussed above, which extends from a top end of the bonding wedge tool 26 and opens proximate to the wedge tip. In one or more embodiments, the two wires 22, 24 may be fed within the vertical hole 32 and exit from it prior to entering the guide channel 34, located through the wedge tip. In one or more embodiments, the wedge tip may be profiled and have a back (or rear) face 36 and a bottom face 38, which intersect substantially perpendicularly from each other, as shown in FIG. 3A, or which can may joined by a beveled surface 39, as shown in FIG. 4B. The example of configurations of the bonding wedge tool 26 with the flat bottom face 38 is used for the purposes of illustration only. Accordingly, the scope of the invention should not be considered limited to these specific configurations. In one or more embodiments, a groove may or may not be provided in the bottom face 38. As discussed above, the vertical hole 32 may or may not be present in the wedge tip. In one or more embodiments of the bonding wedge tool 26 without a vertical hole, the two wires 22, 24 may be guided directly within the guide channel 34, the shape and configuration of the guide channel 34 ensuring that the two wires 22, 24 pass through it side by side.

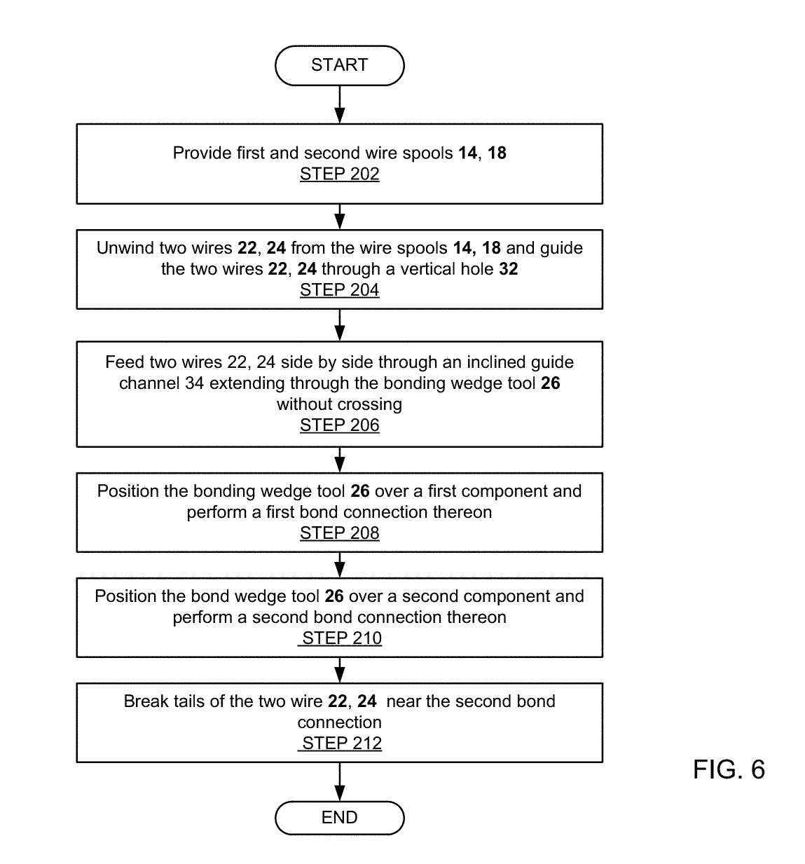

Referring to FIGS. 4, 4A, 5 and 5A, the guide channel 34 extends from the back face 36 to the bottom face 38 of the bonding wedge tool 26. In one or more embodiments, the guide channel 34 has a rectangular cross-section which allows feeding the two wires 22, 24 through the guide channel 34 so that they are parallel and side by side from one another. In one or more embodiments, the rectangular cross-section has a width W of about 2.5 times the diameter of the two wires 22, 24 and a height H of about 1.5 times the diameter of the two wires 22, 24. In one or more embodiments, these dimensions facilitate delivery of the two wires 22, 24 side by side, without crossing, for double wire bond connections. Thus, in one or more embodiments, the geometry of the bonding wedge tool is modified to achieve the optimal arrangement in which the two wires being simultaneously bonded do not cross each other. In one or more embodiments, the cross-section of the guide channel 34 may alternatively be oblong, oval or radius-cornered rectangle. In one or more embodiments, the same wire diameter may be used for simultaneous double wire bond connections. In one or more embodiments, the width W and the height H of the rectangular guide channel 34 may have different ratios to the diameters of the two wires without departing from the scope of the invention, for example, ones of commercially available guide channels.

Referring to FIGS. 4A and 4B, the back and bottom faces 36, 38 may be joined by the beveled surface 39. In one or more embodiments, the angle δ of the guide channel 34 relative to a frontward portion 38a of the bottom face 38 of the bonding wedge tool 26 may be between 30 and 60 degrees and preferably of about 45 degrees. In one or more embodiments, a front face 37 and frontward portion 38a of the bottom face 38 may be perpendicular relative to one another. The frontward portion 38a may be concave, which allows precise positioning of the two wires 22, 24 under the bonding wedge tool 26 while keeping the two wires together during the “welding phase” of the bonding process. This example of the bonding wedge tool 26, 0.75 inches long and adapted for RF signals realized with gold wires having a diameter of 0.001 inches (25 microns) with a shape illustrated in FIGS. 4A and 4B, is used for the purposes of illustration only. Accordingly, the scope of the invention should not be considered limited to these specific applications or specific shapes. For example, embodiments of the invention may be adapted for any tool length, which may be dependent on the machine and application. One or more embodiments of such a bonding wedge tool may also be used in other applications, using wire material other than gold, such as aluminum or copper. In one or more embodiments, the pair of wires may have different diameters and/or a bonding wedge tool of a different shape may also be used, as long as the ratio of the width W vs. height H of the guide channel 34 (as indicated in FIG. 4A) is maintained.

Further, in FIG. 4A, the wire entering the channel near the notation “H” may be round, and not square as shown.

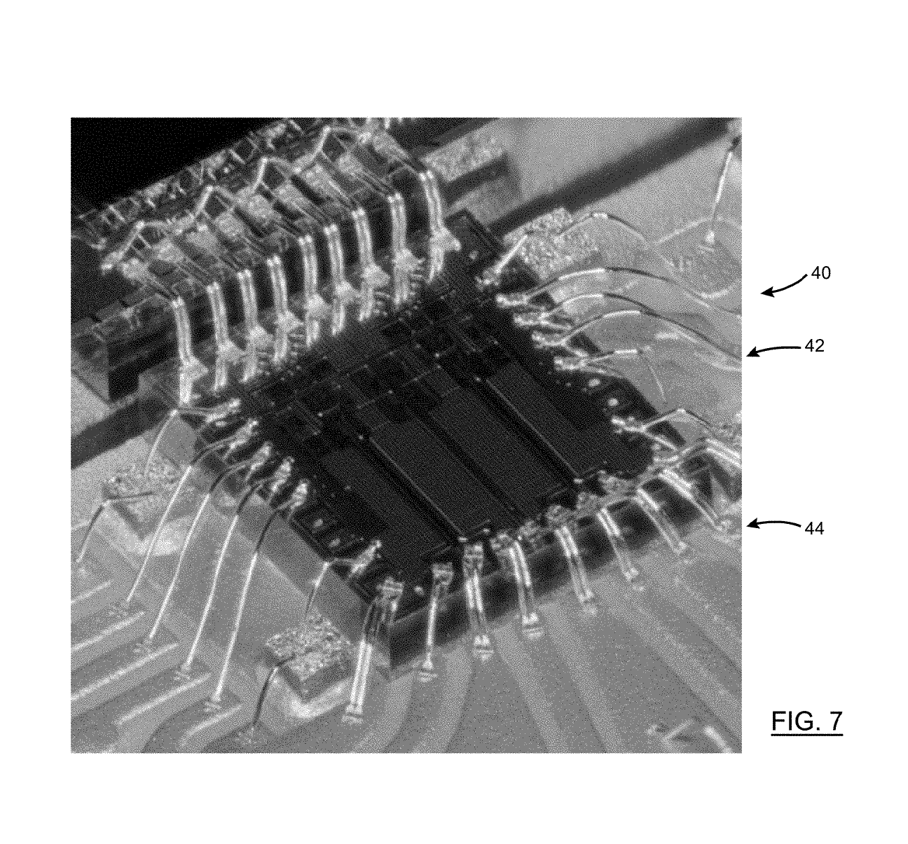

FIG. 6 shows a flowchart in accordance with one or more embodiments of the invention. The flowchart depicts a method of simultaneously connecting two wires to a first component and then a second component in accordance with one or more embodiments of the invention. One or more of the steps in FIG. 6 may be performed by the components of the wire wedge bonding system 10, discussed above in reference to FIGS. 1-5. In one or more embodiments of the invention, one or more of the steps shown in FIG. 6 may be omitted, repeated, and/or performed in a different order than the order shown in FIG. 6. Accordingly, the scope of the invention should not be considered limited to the specific arrangement of steps shown in FIG. 6.

In Step 202, first and second wire spools 14, 18 are provided. The second wire spool 18 is located higher and offset relative to the first wire spool 14. Those skilled in the art will appreciate that there may be more than two wire spools. The bond wedge tool facilitates the addition of two or more spools. In Step 204, two wires 22, 24 are unwound from the wire spools 14, 18 and guided side by side (in parallel) through the vertical hole 32 extending through the wedge bonding tool 26. In Step 206, the two wires 22, 24 are fed in parallel through the guide channel 34 at the lower end of the bonding wedge tool 26, without crossing. In Step 208, the bonding wedge tool 26 is positioned over a first component and a first bond connection is made thereon. In one or more embodiments, the first component may be an IC package. Alternatively, the first component may be a bond pad of a substrate. In Step 210, the bonding wedge tool is positioned over a second component and a second bond connection is made thereon. In one or more embodiments, the second component may be the same bond pad of a substrate as the first component. Alternatively, the second component may be a different bond pad of the substrate. Finally, in Step 212, the tails of the two wires 22, 24 near the second bond connection are broken.

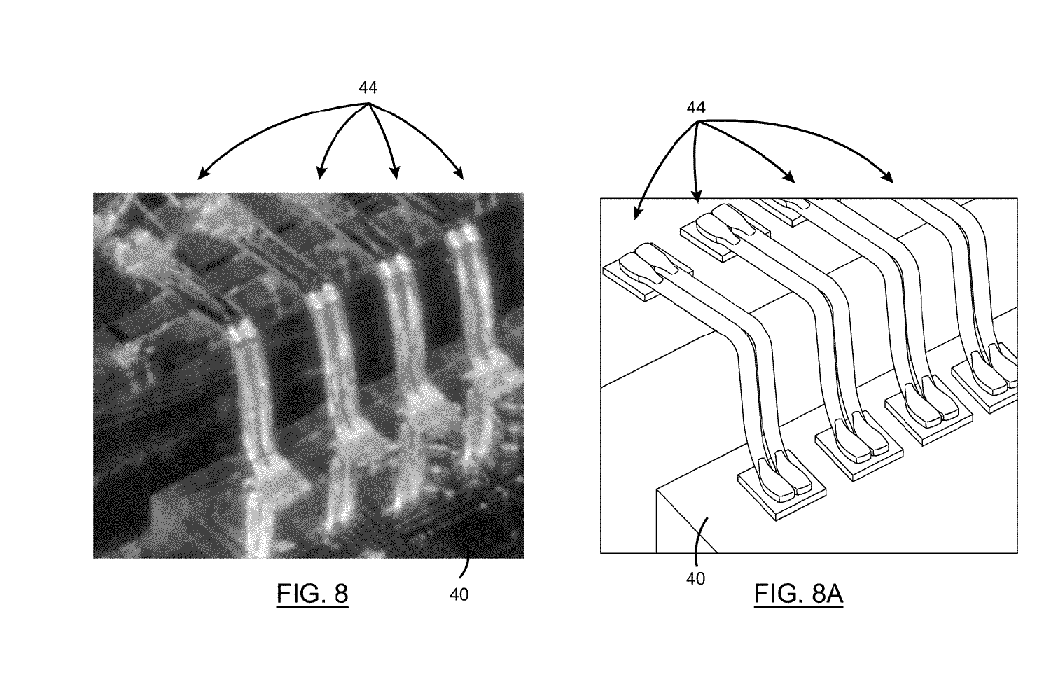

FIG. 7 shows an integrated circuit (IC) package 40 connected to a substrate with both single 42 and double 44 wire bond connections. The single and double wire bond connections were made using an existing wire wedge bonding system, modified with the addition of a second wire spool, and with the bonding wedge tool 26 as described above. The modified bonding wedge tool 26 may be used for single and double wire bond connections. For single wire connections, the wire 24 from the second wire spool 18 may not be used.

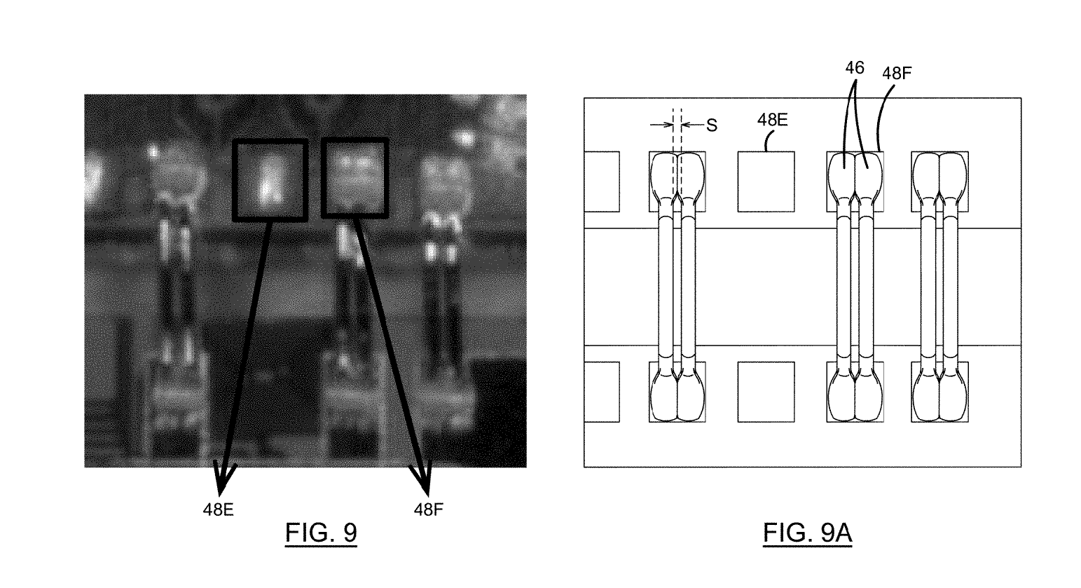

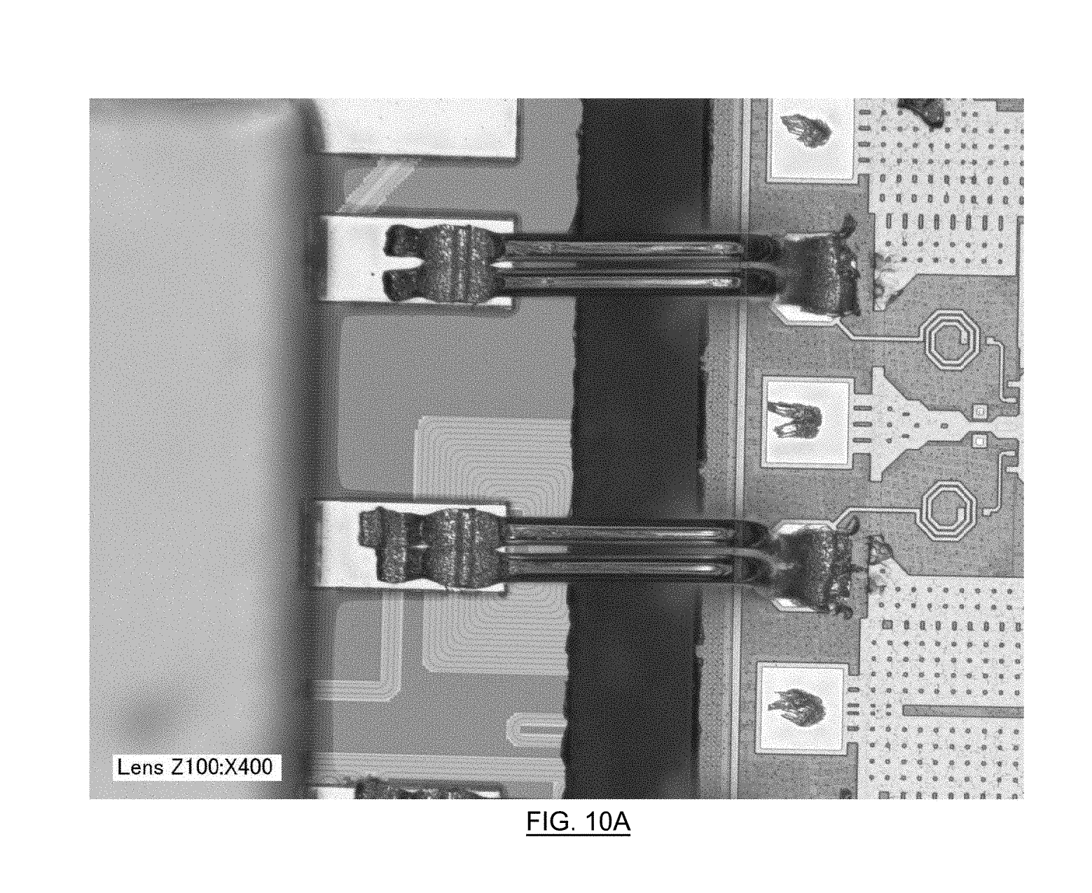

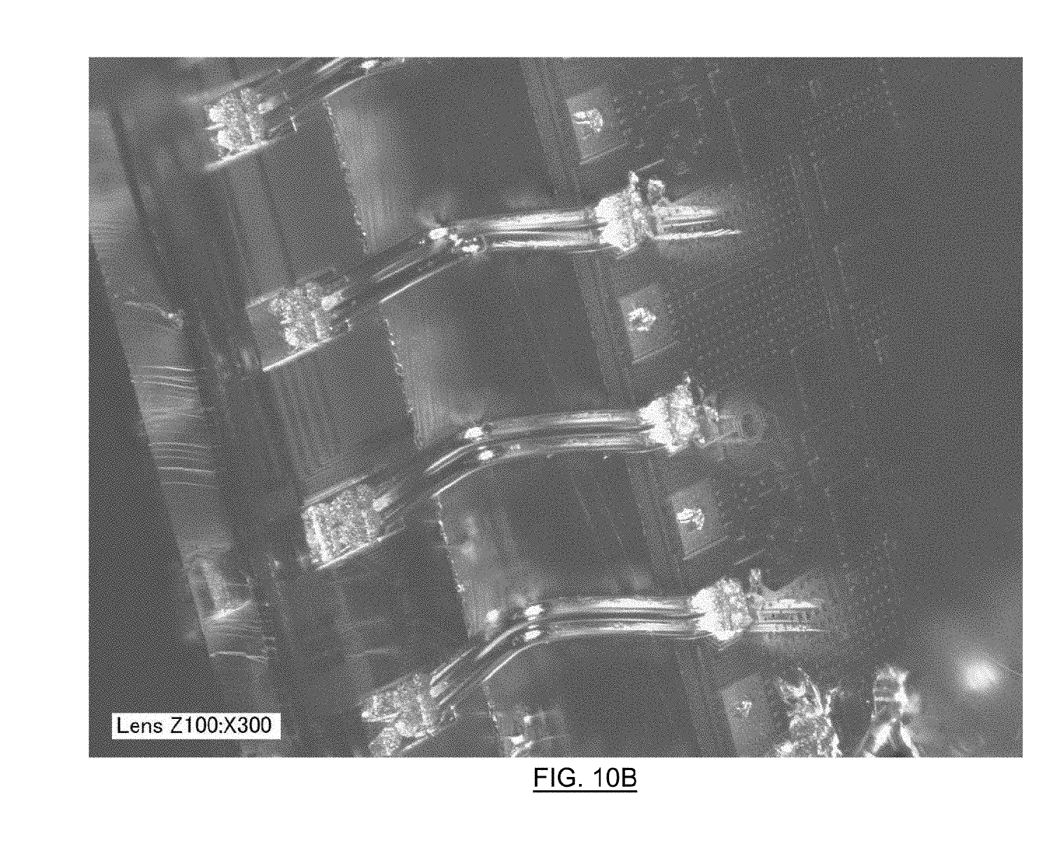

Referring now to FIGS. 8, 8A, 9, 9A, 10A and 10B the double wire bond connections 44 are shown in greater detail. In FIGS. 9 and 9A, two wire segments of one of the double wire connections 44 are of the same length, which may minimize, if not eliminate, skew delays between the two wire segments. The two wire segments are slightly spaced apart at a distance S of about 10 microns, which is small enough to allow connections on the same bonding pad 48 while being sufficient to minimize cross-talk between the segments. FIG. 9A illustrates two bond feet 46 extend fully over the bonding pad 48. Reference 48E indicates an empty pad, while reference 48F indicates a bonding pad with two double wire connections. Distributing electrical current at surfaces of conducting materials (e.g. wires and a bonding pad) may decrease the inductance of the wire bond connections.

While FIGS. 1-10 show specific configurations of a wire wedge bonding system with two wire spools, other configurations may be used without departing from the scope of the invention. For example, one or more embodiments may allow simultaneously connect two wires 22, 24 to a first electronic component, and then to a second electronic component. While generally wire bond connections are to connect a substrate to an integrated circuit (IC) package, one or more embodiments may be used to connect two IC packages, or two substrates.

FIGS. 1-10 generally illustrate the wire wedge bonding system provided with the bonding wedge tool 26 having a guide channel 34 at its lower end. In one or more embodiments, the wedge bonding tool 26 may also include a vertical hole 32. The two wires 22, 24 are fed side by side within the guide channel 34. The bonding wedge tool 26 is then positioned on a first bonding pad of the first electronic component. If the two wires 22, 24 are gold wires, a thermosonic process may be used, which consists in providing a combination of ultrasonic energy and pressure to the bonding wedge tool 26. Other bonding processes may be used, depending on types of wires used for wire bond connections. One or more embodiments of the wedge bonging method allows simultaneously connecting the two wires 22, 24 to the first bonding pad. The bonding wedge tool 26 is then moved towards the second component and positioned on a second bonding pad on the second electronic component. Energy is provided by the wire wedge bonding system 10 to simultaneously bond the two wires 22, 24, and the tails of the two wires 22, 24 are then broken near the second bonding pad, leaving the two wire segments connecting the first and the second electrical components.

Finally, one or more embodiments may be used as a kit, to modify a single wire wedge bonding system for single wire bond connections. The kit includes a second wire spool support 16 which is connectable to the single wire wedge bonding system. The second wire support 16 allows holding a second wire spool 18, above and offset relative to an existing wire spool support of the single wire wedge bonding system. The kit also includes the bonding wedge tool 26, modified for double wire bond connections, which has the rectangular cross-section guide channel 34 opening at the rear face of the bonding wedge tool (relative to the displacement direction of the wedge) and on its bottom face, and also preferably a vertical hole 32.

Referring back to FIG. 1, a prototype of the double wire wedge bonding system was made with such a kit from a single wire wedge bonding system, Kulicke & Soffa machine, model number 4523 AD. With this system, the second wire spool support 16 was designed and installed above the first existing wire spool, to support a second wire spool 18. The existing bonding wedge tool was also replaced by a modified bonding wedge 26 which allows performing two wire bond connections simultaneously. Each of the two wires 22, 24 from the first and the second wire spools 14, 18 is guided by the existing wire guide 30 and the wire clamp 28 prior to being fed through the vertical hole 32 of the body of the bonding wedge tool 26. The two wires 22, 24 exit at the bottom aperture of vertical hole 32 and are passed back through a guide channel 34 having a rectangular cross-section, which allows installing and soldering ends of the two wire simultaneously.

Simultaneous double wire bond connections as discussed above may decrease the resulting inductance of the connection; maximize the use of the connection surface of the bonding pads; provide wire segments of equal length, thereby minimizing skew delays; locate wires side by side, thereby minimizing cross-talk between the wires, and/or increasing the reliability resulting from the redundancy in the connection.

One or more embodiments may provide a wire bond connection with two wire segments remaining parallel to one another at all points between the two bonding pads and allowing the bonding of two wires with a diameter of 25 microns, for example, on a small bonding pad having a side length of 80 microns, for example. In one or more embodiments, simultaneous double wire bond connection may be performed by a standard wire wedge bonding system, without the need for precise control as in sequential double wire wedge bonding.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A wedge bonding method for simultaneously connecting two wires to a first component and then to a second component, comprising:
a) feeding the two wires side by side through a guide channel located at a lower end of a bonding wedge tool;
b) positioning the bonding wedge tool over the first component and performing a first bond connection thereon;
c) positioning the bonding wedge tool over the second component and performing a second bond connection thereon; and
d) breaking tails of the two wires near the second bond connection.

2. The method according to claim 1, further comprising providing first and second wire spools, the second wire spool being located higher and offset relative to the first wire spool.

3. The method according to claim 2, further comprising:
unwinding the two wires from the first and the second wire spools, respectively; and
guiding the two wires side by side through the guide channel extending through the bonding wedge tool, prior to step a).

4. The method according to claim 3, wherein during the step of guiding the two wires, the two wires are spaced apart.

5. The method according to claim 1, wherein during steps b) and c), the two wires are spaced apart by 8 to 13 micrometers.

6. The method according to claim 1, wherein
the two wires have the same diameter, and
in step a), the guide channel has a cross-section of rectangular, oblong, oval or radius-cornered rectangle shape, with a width of 2.3 to 2.7 times the diameter, and a height of 1.4 to 1.7 times the diameter.

7. The method according to claim 1, wherein the first component is an integrated circuit package and the second component is a bond pad of a substrate.

8. The method according to claim 7, wherein
the lower end of the bonding wedge tool is provided with a back face and a bottom face, and
the guide channel extends through the lower end and opens on the back and bottom faces.

9. A bonding wedge tool for simultaneously connecting two wires to a first component, and then to a second component, comprising:
a vertical hole extending therethrough, from a top aperture to a bottom aperture of the bonding wedge tool;
a back face and a bottom face at a tapered lower end of the bonding wedge tool; and
a guide channel opening on the back and the bottom faces.

10. The bonding wedge tool according to claim 9, wherein a frontward portion of the bottom face is concave.

11. The bonding wedge tool according to claim 9, wherein
the guide channel has a rectangular cross-section, with a width of 2.3 to 2.7 times the diameter, and a height of 1.4 to 1.7 times the diameter, at the back and the bottom faces of the bonding wedge tool.

12. A wedge bonding kit for modifying a single wire wedge bonding system, which includes a first wire spool support folding a first wire spool and a single wire bonding wedge tool, for simultaneously connecting two wires to a first component, and then to a second component, comprising:
a second wire spool support which is connectable to the single wire wedge bonding system, and located above and offset relative to the first wire spool support of the single wire wedge bonding system.
the bonding wedge tool according to claim 9.

13. The wedge bonding kit of claim 13, wherein a distance between the second wire spool support and the bonding wedge tool is between 5 cm and 80 cm.

14. The wedge bonding kit of claim 13, wherein the distance is optimized to ensure that the two wires do not cross each other.

15. A wedge bonding system for simultaneously connecting two wires to a first component, and then to a second component, comprising:
a bonder for generating ultrasonic energy, force and time control required to connect the two wires to the first and the second components;
a frame, operatively connected to the bonder;
first and second wire spool supports operatively mounted to the frame, for supporting first and second wire spools of the first and the second wires, the second wire spool support being higher and offset relative to the first wire spool support;
the bonding wedge tool according to claim 9; and
a clamp, for guiding the first and the second wires side by side prior to entering the guide channel, wherein
the wire clamp being located above the bonding wedge tool and substantially aligned with the top aperture of the bonding wedge tool.

16. The wedge bonding system according to claim 15, wherein the angle between the first and the second wire spools is between 20 to 40 degrees.

17. The wedge bonding system according to claim 15, further comprising a wire guide located above the clamp.

18. The wedge bonding system according to claim 15, wherein the two wires have the same diameter.
